(19) United States
(12) Patent Application Publication
(10) Pub. No.: US 2008/0265822 A1
(43) Pub. Date: Oct. 30, 2008

(54) Class G motor drive

(75) Inventors: Paolo Menegoli, San Jose, CA (US); Carl Sawtell, San Jose, CA (US)

Correspondence Address: Paolo Menegoli;c/o Acutechnology Semiconductor Inc., Suite 52, 3487 McKee Road, San Jose, CA, 95127, US

(73) Assignee: Acutechnology Semiconductor Inc.

(21) Appl. No.: 11/790,306

(22) Filed: Apr. 25, 2007

(51) Int. Cl. G05B 19/18; H03F 3/04

(52) U.S. Cl. 318/569; 330/297

(57) ABSTRACT

A method for driving a motor by using an output stage amplifier that operates between two or more separate supply voltages, depending on the amplitude of the input signal, is presented. This bridge unipolar class G stage allows driving the motor with high accuracy and improved efficiency without introducing switching noise typical of PWM motor driving. This method can be applied with the same benefits to class AB, pseudo class AB or to class A output stages. When this method is associated with an imposed current driving approach and with a current oversampling digital to analog converter the resulting advantages are very significant.

### BACKGROUND OF THE INVENTION

1.Field Of The Invention

The present invention is in the field of motor controllers. The present invention further relates to Hard Disk Drives and optical data storage devices. The present invention further relates to methods and circuits for controlling a voice coil motor for positioning the read/write head of a hard disk drive. The implementation is not limited to a specific technology, and applies to either the invention as an individual component or to inclusion of the present invention within larger systems which may be combined into a larger integrated circuit.

The invention also falls within the field of integrated circuits to drive a motor.

2. Brief Description of Related Art

The physical kinetic parameters of a motor such as velocity and acceleration are directly linked to its torque which, in its turn, is directly dependent on the current applied to the motor itself. That is why most motors are driven in current by means of a control loop that senses the current in the motor and regulates it according to a desired value.

In several fields the accurate control of position, velocity and acceleration of a motor is critical to the overall performance of the system. Some of these fields are: the hard disk drive applications, the optical data storage motor positioning applications, the digital still camera applications to control focus, zoom and other dedicated motors, the printer applications, the robotics and others.

The position of the read/write head of a disk drive is typically controlled by a linear motor, often referred to as the Voice Coil Motor (VCM) that moves a mechanical arm over the disk surface. The VCM 4, as shown in FIG. 1, is represented as an inductor L1 in series to a resistor R1 to indicate the main electrical parameters of the motor. This representation does not include the Back Electromotive Force (BEMF) that is generally represented as a voltage generator whose value is dependent on the velocity of the motor. The VCM is driven in response to a control loop, known as the servo loop, whose main algorithm is implemented typically within a microprocessor or similar digital processor, and is typically driven in at least three different modes.

A “seek” mode causes the read/write head to move from one track on the disk to a potentially unrelated track, which may require a significant motion. In this mode, the control system typically attempts to control the velocity of the mechanism. In “track follow” mode, the read/write head is relatively stationary, and the control system works to control its precise position to be directly above the appropriate track. In a third mode, the head is driven onto or off of the disk surface to a “park” position, typically using a mechanical ramp to pull the head above the surface of the disk.

As shown in FIG. 1, the VCM control system comprises a serial port 1 that communicates with the microprocessor that contains the main servo algorithm and that drives, with digital signals, a digital to analog converter (DAC) 2. This DAC 2 typically drives a VCM actuator 50 in its various forms and implementations. The VCM actuator 50 commands the current into the VCM 4 which defines its arm's velocity and position on the disk surface.

In addition to the servo loop there is, typically, an inner analog current control loop that drives the VCM as shown in more details in FIG. 1. The serial port 1 drives a Digital to Analog Converter (DAC) 2 which, in its turn, commands the current through the inner current control loop. In this case the VCM actuator block 50 comprises the inner analog current control loop to regulate the current into the VCM 4.

In order to obtain optimal control, the overall servo loop commands a particular current to be driven into the VCM, and an inner analog control loop regulates the current. Practical circuit implementation considerations require that the VCM be driven with conventional amplifiers which impose a voltage across the VCM. The local analog control loop senses the current in the VCM, compares it to the commanded current, and adjusts the drive voltage to maintain the desired current.

The inner analog control loop is driven by a DAC 2 creating an analog representation of the digitally commanded current, and a Current Sense Amplifier (CSA) 5 generates a signal representing the instantaneous value of the VCM current. These two signals are summed at the input of the error amplifier 6 via resistors R2 and R3 respectively, and this sum is the error in the value of the current. The voltage reference 3 sets the common mode voltage at the load.

The error amplifier 6 is conventionally an integrator, with arbitrarily high gain at DC but with gain falling with frequency to maintain the stability of the loop at higher frequencies. This stage might also implement additional frequency/phase shaping for stability. Such frequency response shaping is controlled by C1, C2 and R4, as is well known in the art. The output of error amplifier 6 feeds the pseudo class AB stages 9 and 10 which are typically constituted of two anti-phase linear amplifiers 7 and 8, coupled to a “full bridge” capable of applying the full supply voltage across the load in either polarity. In series with the VCM 4 there is a power resistor R5 used to sense current. The voltage across this current sense resistor R5 is used as the differential input to the current sense amplifier 5.

Within this loop, the error amplifier is a large bandwidth standard operational amplifier. The DC errors can be initialized out of the loop with software, during the so called “calibration phase” and the AC requirements are generally met with conventional design techniques. The VCM power amplifier 7 is similarly very conventional in design. Typical Class AB stages are implemented with complementary components biased with a stand-by current and feature very low zero-cross distortion.

Zero-cross distortion is an important parameter to measure the ability of the driver to exhibit zero current in the motor when zero current is desired. The so-called “jumps” or “dead-bands” in the transfer function of the amplifier are highly undesirable and typically minimized by the use of class AB stages. When the stages are biased in a similar manner using non-complementary components, as is often the case for the integrated motor driver circuits, they are generally known as pseudo-class AB amplifiers.

The overall analog control system, including DAC, current sense amplifier, error amplifier and power amplifiers is typically implemented on a single chip, usually along with the control and power stage for the disk drive spindle motor actuator and any other analog/power functions required in the system. The resultant chip's efficiency is determined by the efficiency of all the subsystems, but in particular the product of current and voltage for the output transistors in the diverse conditions of the motor drive is the main contributor to the power dissipation in the chip.

In the case of the VCM, depending on the modes of operation, the drive may be more or less efficient. Typically in “track follow” mode the current is not very significant, but the voltage might be (depending on the voltage common mode of the output stage). In “track follow” the current is mainly due to the fact that the arm of the VCM has to overcome the spring force of the flexible connector that carries the conductors for the pre-amplifier located on the tip of the arm, therefore the current is depending on the location of the arm, whether it is closer to the center or to the outer track of the disk. In “seek” mode the current is quite high, but the voltage between drain and source of the power transistors of the bridge output stage is generally not very high, since they are typically operating in the triode region.

Generally the maximum power dissipation occurs during the transition between these two main modes of operation and more specifically during the acceleration and deceleration of the VCM arm, when the product of current and voltage applied to the power stages in the chip is significant also for effect of the back electromotive force. In fact, in order to optimize the mechanical response of the motor and minimize the seek time a pseudo-sinusoidal profile is given to the current in the motor.

Nowadays several efforts are increasingly made to improve the overall efficiency of the motor drive especially for the case of battery operated disk drive or more generally motor drives. Class AB amplifiers, although featuring low overall distortion, are constantly biased at a not negligible stand-by current.

The utilization of PWM switching approaches, such as driving a motor in class-D or with more traditional PWM control loops, introduces high frequency switching noise that can interfere with the operation of the device. In the case of the VCM, the Hard Disk Drive manufacturers have been reluctant to employ these approaches despite of their recognized advantages in terms of reduced power dissipation.

The proliferating use of miniature precision motor drive in battery operated devices is posing two formidable related problems: a) extending the time between charges and b) being able to dissipate the necessary power in order to keep the device temperature within reasonable ranges.

The solution to both these problems is to find accurate and more efficient means to drive the motors. In particular for brushless DC motors used in Hard Disk Drive and data storage devices, as well as in digital still cameras, the efficiency is becoming a very critical aspect of their overall performance. The typical case could be the VCM of the Hard Disk Drive. In this case, even for desktop applications, that are not battery operated, the efficiency is increasingly an important factor due to the fact that higher processor speeds, within the personal computer case, tend to raise the temperature rapidly.

The use of PWM motor drives that apply an average voltage at the terminals of the motor driving fully on or fully off the power transistors at frequencies in the range of 100 KHz to a few MHz is very well known to those skilled in the art. However these schemes have several disadvantages like higher harmonic distortion, higher complexity and most importantly the Electro Magnetic Interference (EMI) effects generated by the fast voltage rising and falling edges at the motor terminals.

In particular, the EMI has limited the use of switching drive methods in cases like the Voice Coil Motor drive especially in “track follow”. The proposed invention makes use of output stages that get current from different supply voltages depending on the amplitude of the input signal similarly to the known class G stages utilized for audio amplifiers and DSL line drivers.

Class G amplifiers operate to switch the power supply rail from a lower voltage one, when the output signal has low swing, to a higher voltage one when larger output swings are required. Class G operation is more frequently implemented with a single class AB output stage that is connected to two power supply rails by a diode or a transistor switch. The stage is designed such that the output stage is nominally connected to the lower supply voltage, and automatically switches to the higher power supply rails for large signal peaks.

Another approach involves the use of two class AB output stages, each connected to a different power supply voltage, with the magnitude of the input signal determining the signal path. Using two power supplies improves efficiency enough to allow significantly more power for given size and weight.

The first official document describing a rudimentary approach similar to what is nowadays known as class G output stage, is Sampei (U.S. Pat. No. 3,961,280). Sampei in 1973 described a simple emitter follower stage implemented with bipolar transistors that, depending on the input signal amplitude, derived power from one of the connected power sources, automatically disabling the lower voltage ones through the use of series diodes. Although this implementation does not provide the performances of modern class G amplifiers, it certainly characterizes the main concept.

Similarly Sunderland (U.S. Pat. No. 4,319,199) in its FIG. 9, describes a single ended, dual supply class AB amplifier with various parallel stages powered from different power sources operating at staggered voltage levels, that are activated depending on the amplitude of the input signal in order to achieve better efficiency.

Dijkmans et al. (U.S. Pat. No. 4,706,039) describes a class G amplifier implemented with bipolar and MOS transistors (FIG. 8) with single ended output, single and dual supply with a parallel stage activated by the varying amplitude of the input signal, configured to provide higher efficiency than the stages described in the previously mentioned US patent documents.

LaRosa et al. (U.S. Pat. No. 4,721,919) describes a bridge class G amplifier with unipolar supply where a series transistor device is switched in as needed to follow the amplified signal and allow the output voltage to increase.

Harvey (U.S. Pat. No. 6,538,514) depicts a typical low distorsion class G amplifier implemented as extension of a single ended, dual supply class AB stage with the addition of a series device connected to a higher power supply that is selected as the active signal path in response to the amplitude of the input signal. More specifically Harvey teaches a compensation method for the stage.

Quartfoot et al. (U.S. Pat. No. 6,614,310) discloses a class G DSL line driver amplifier with two sets of power supplies that are alternatively selected through series switches based on the amplitude of the signal being transmitted.

The European Patent FR2667461 “Module Amplificateur De Classe G” by Marc Gavard et al., describes a class G bridge stage utilizing bipolar transistors, within which a second high side parallel stage is activated by a switch driven by a comparator output when higher power supply is needed to drive the stage output.

Sommerville et al. (U.S. Pat. No. 6,838,942) describes a single ended unipolar class G amplifier with multiple MOS current mirrors biased at different supply voltages that get activated based on the amplitude of the input signal.

Maclean et al. (U.S. Pat. No. 7,177,418) discloses a class G amplifier and method for switching between power supply rail voltages for a differential driver device using power MOSFET transistors.

All the above-mentioned documents describe prior art class G amplifiers that are mainly used in Audio and DSL applications. The present invention proposes a class G bridge stage that is specifically directed at current driven motor drivers and it differentiates from all the prior art for the fact that it is an unipolar, bridge, parallel approach implemented in a unique and very effective way. This represents a valid alternative to PWM schemes for motor drives.

In the Hard Disk Drive (HDD) systems the density of the magnetic data recorded on the disk is increasing very rapidly and that is translated in the number of rotational tracks per inch on the disk surface. The tracks containing the magnetic data are consequently getting narrower and the burden to stay on track with limited Bit Error Rate (BER) during normal operation is shifted to the ability to control the position of the head on the disk with increasing accuracy.

It is therefore advantageous to reduce as much as possible the sources of electrical noise in the overall drive control loop so that the effective dynamic range is improved. Furthermore the switching noise introduced by PWM schemes may result unacceptable in the case of data storage systems that utilize magnetic media.

Accordingly, what is needed is a motor actuator that drives the motor with accuracy and high efficiency while maintaining very low cross-over distortion and without introducing the undesirable EMI effects typical of switching amplifiers (class-D) and of Pulse Width Modulation systems in general.

### SUMMARY OF THE INVENTION

It is an object of the present invention to provide a VCM driver that improves upon the efficiency of the motor drive maintaining a linear approach. The utilization of PWM or PSM ( Phase Shift Modulation) switching approaches, such as driving a motor in class-D or with more traditional PWM control loops, introduces high frequency switching noise that can interfere with the operation of the device. In the case of the VCM, the Hard Disk Drive manufacturers are reluctant to employ these approaches despite of their recognized advantages in terms of reduced power dissipation.

One of the main advantages of the described configuration is the fact that it resolves the important problem of efficiency and power dissipation without degrading the resolution of the motor drive or the accuracy of the control and without adding much complexity and cost.

It is another objective of the present invention to provide a VCM driver, or more generally a motor driver, that combines the advantage of higher efficiency with the direct imposition of a current in the motor by selecting its polarity based on the DAC digital input therefore removing the DC error sources. This would eliminate the calibration phase, reducing the time needed to start the hard disk drive operation.

It is another objective of the present invention to provide a VCM driver, or a more generally a motor drive, that combines the above mentioned advantages with a “current” oversampling digital to analog converter to replace the most traditional voltage DAC in order to reduce the total current consumption of the chip, its die size and complexity and more importantly to increase the resolution of the motor control.

The power stage of a VCM motor drive is typically configured as a full bridge, with two low side drivers and two high side drivers. The full bridge configuration allows the application of the full current to the load in both directions. The high side transistors may be P-type MOS or DMOS devices or N-type MOS or DMOS devices.

Typically a Hard Disk Drive includes two separate power supplies at different voltage levels. A current desktop computer HDD makes use of a 12V supply and a 5V supply. Similarly a notebook computer HDD utilizes two power supplies: one at higher voltage and one at lower voltage. Generally the motor drive full bridge power devices are tied to the highest supply voltage.

The present invention employs the traditional full bridge with the addition of two more power devices tied to the lower supply voltage through a series diode or a switch. In the proposed configuration, these two new power devices are the high side drivers. Typically these power devices may be implemented with MOS transistors. Two control blocks drive the six power devices (3 per each half bridge). The devices may be driven in class AB or, more simply, in class A obtaining very low cross-over distortion.

If driven in class A, the low side drivers always conduct a current that can be increased depending on the amplitude of the input signal. This can be achieved by forcing a constant common mode voltage at the outputs of the bridge. When the required load current is low enough that it can be provided by the high side devices tied to the lower power supply, the control blocks would prevalently drive these high side transistors coupled to the lower voltage rail. When the required load current is increased, as in the case of seek mode operation, automatically the high side devices connected to the higher voltage power supply are activated and the high side devices coupled to the lower voltage rail are de-biased allowing higher voltage across the load.

In the proposed embodiment, shown in FIG. 2, a diode D1 is connected in series to the high side power transistors coupled to the lower voltage rail VDD in order to prevent a current flow from the higher voltage power supply to the lower voltage one. This diode could, more efficiently, be replaced by a switch that is turned on and off simultaneously with the lower voltage high side transistors. During the transition between the two supply rails, both high side transistors conduct in parallel in order to obtain a smooth handoff, very low harmonic distortion and accurate current control.

This smooth transition can be achieved in many ways. One proposed means is to drive the gates of the two high side devices with the same signal but with the addition of a voltage offset between the gate of the lower voltage high side device and the gate of the higher voltage high side device. The amplitude of the voltage offset governs the conduction overlap between the transistors. For the effect of this voltage offset, the gate voltage of the high side transistors tied to the lower voltage supply rail are biased at higher voltage with respect to the gates of the high side transistors coupled to the higher voltage rail. This has the effect of turning on the higher voltage high side transistors only after the lower voltage rail high side devices have approached the triode region. This voltage offset can be implemented in many ways, for example as a voltage drop on a resistor or a diode. It is not important that these voltage offsets on the two sides of the bridge maintain a perfect match.

It is important to note that the addition of the two high side devices and the switch in series to the lower voltage supply rail does not add significant cost because these components do not need to have very low on resistance since they normally do not need to be conducting very large currents.

Another advantage of this solution is that during “track follow” operation, when high resolution is required to control the reading and writing of data on the hard disk, the high voltage supply noise, that is utilized to supply power to the spindle motor, is not affecting the VCM drive because the current is supplied by the lower voltage power supply.

In a further embodiment of the present invention as depicted in FIG. 3, the class G operation can be achieved by eliminating the inner current control loop as described in Menegoli et al. (U.S. patent application Ser. No. 11/516,481). In this proposed implementation an additional MOS transistor is connected in series to the low side devices to impose the load current in response to a current digital to analog converter. This device is part of a power current mirror that can be implemented in many ways in order to achieve the requested accuracy and linearity.

This additional transistor does not add to the total series resistance of the load, with respect to the more traditional approach, because generally an external power resistor (of approximately 250 mohms) is used to sense the current. This sense resistor contributes significantly to the voltage drop at the load, limiting the maximum motor current and the “seek” time and it is no longer needed in the present approach. Modern CMOS process technologies allow the utilization of 200 mohm on resistance low voltage NMOS devices without requiring a very significant silicon area.

In this configuration an operational amplifier drives the high side drivers in order to regulate the voltage at the drain of the power current mirror device at a given reference voltage. Therefore the additional power current mirror device can be implemented as a low voltage MOS transistor. Two switches driven by the MSB of the DAC determine which high side of the bridge has to be conducting current, determining the polarity of the load current.

The gate voltage of the high side transistors are offset by a voltage such that for relatively low load currents the high side transistors powered by the lower voltage supply are conducting, while for higher load currents, when the output of the operational amplifier driving the gates is increasing its voltage, the high side transistors electrically coupled to the higher voltage supply are conducting. For intermediate values of load current there is a transition point at which both high side transistors are conducting and this transition point is dependent on the voltage offset between the gate voltages of the high side devices. This transition point of overlapping conduction of the high side transistors determines the performance of the class G stage in terms of zero-cross distortion.

In addition to the removal of the current control loop, this implementation allows further circuit simplification because the low side drivers are also driven “digitally”, either fully on or fully off, controlled by the MSB of the digital to analog converter digital input, and because the mirroring of the current is limited to only one power mirror.

This embodiment of the present invention simplifies enormously the implementation of the VCM driver with the advantages of lower noise, higher efficiency, very low distortion, no need for initial offset calibration phase, faster response to the commanded digital current signal, smaller silicon area, simplified testability, less external components and excellent motor drive resolution, particularly when the DAC is implemented utilizing oversampling techniques as described in Sawtell et al. (U.S. Pat. No. 7,034,490).

In a further embodiment of the present invention, as shown in FIG. 4, the load current is imposed by power current mirrors whose output devices are the low side drivers of the full bridge. The high side drivers are driven by operational amplifiers that regulate the voltage of the drain of the conducting low side device. The two couples of high side drivers are driven with a voltage offset between the gates of the high side transistors similarly to the previously described embodiments.

The side of the bridge to be conducting is still selected by the MSB of the DAC (sign bit) imposing the current. When the current to be imposed to the load exceeds the value that can be applied through the high side connected to the lower voltage power supply, automatically the high side transistor connected to the higher voltage power supply starts conducting the necessary current.

The advantages of this configuration are the same of the implementation of FIG. 3, with the difference that this embodiment does not require the extra power device in series to the bridge. The two low side power current mirrors can be implemented by combining the mirrors in one single mirror and by switching the low side gates based on the polarity of the load current, but particular attention has to be made to the zero-cross distortion.

In particular the latency of the analog signal path through the current mirror has to be equivalent to the latency introduced in the digital signal path to prevent dynamic jumps in the transfer function. Conventional circuit techniques can be applied to obtain very low zero-cross distortion.

It is significant to note that the elimination of the current regulation loop implies the inherent stability of the system, the reduced current consumption yielding to higher efficiency and the faster response to the commanded signal to the DAC because the application of the motor current is set by an open loop circuit and it is not delayed by the integrator time constant.

If, in conjunction with the class G output stage, a means for controlling the output voltage common mode is implemented, much higher efficiency than the traditional class AB output stages can be obtained because the voltage across the low side output transistors conducting the motor current is minimized. It is also advantageous that the drains of the low side drivers are regulated by the high side feedback controls, since excellent current regulation can be achieved independently from the high transconductance of the output devices of the power current mirrors.

As is clear to those skilled in the art, this basic system can be implemented in many specific ways, and the above description is not meant to designate a specific implementation. For example multiple power supply rails with multiple high side transistors could be employed to obtain analogous results. Similarly, this basic system has been described with particular attention to the Hard Disk Drive applications, but it can also be implemented more generally for the control of any motor.

### BRIEF DESCRIPTION OF THE DRAWINGS

Further details of the present invention are explained with the help of the attached drawings in which:

FIG. 1 is a general block diagram showing the prior art of the disk drive VCM control system;

FIG. 2 is a circuit diagram showing a general detailed implementation of the basic VCM control system in accordance with the present invention;

FIG. 3 is a circuit diagram showing a more detailed implementation of the VCM control system with load current imposition technique in accordance with the preferred embodiment of the present invention;

FIG. 4 is a circuit diagram showing a detailed implementation of the VCM control system with dual power current mirroring in accordance with another embodiment of the present invention;

FIG. 5 is showing the most important current waveforms of the class G stage in the case of sinusoidal input signal for various voltage offset amplitudes between the gate drive of the high side transistors in accordance to the embodiment of FIG. 3;

### DETAILED DESCRIPTION OF SPECIFIC EMBODIMENTS

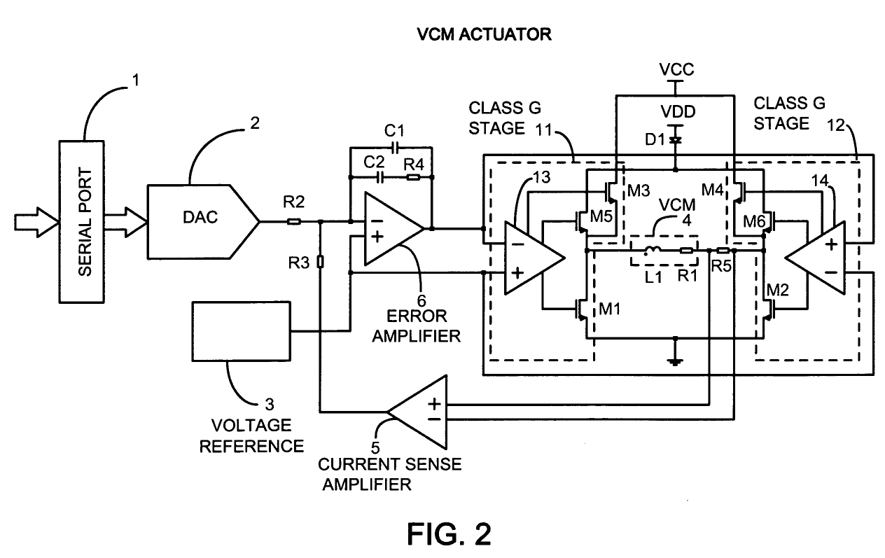

### A. FIG. 2

FIG. 2 shows a general embodiment for the basic VCM driver control system utilizing two Class G stages 11 and 12. The blocks 13 and 14 drive the gates of the low side power transistors M1 and M2, the gates of the high side power transistors M3 and M4 electrically coupled to the higher voltage power supply designated as VCC, and the gates of the high side power transistors M5 and M6 electrically coupled to the lower voltage power supply designated as VDD through the series diode D1.

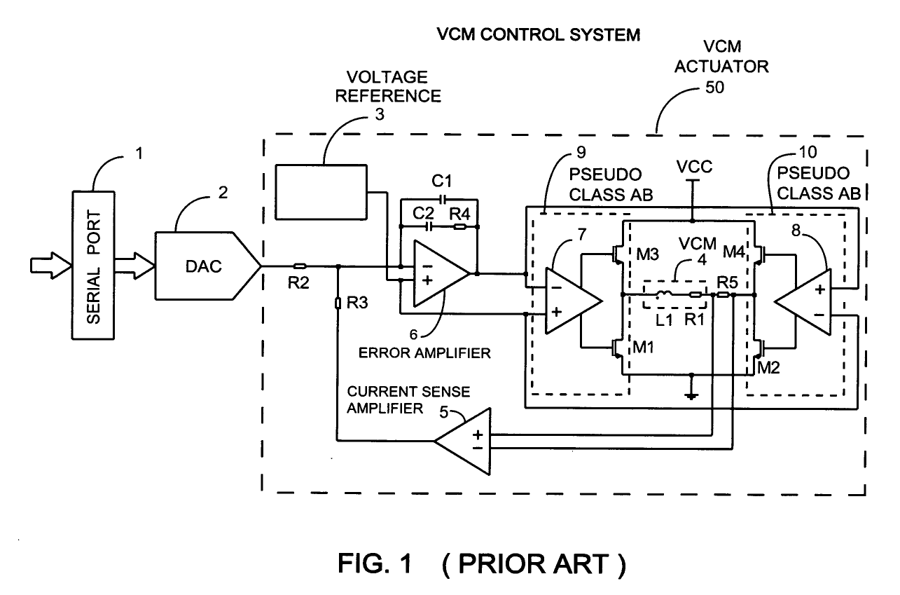

The embodiment of FIG. 2 is very similar to the classical implementation of the prior art described in FIG. 1, since there is an inner current control loop that regulates the load current sensed as the voltage drop on the resistor R5 and amplified by the operational amplifier 5. An error amplifier 6 drives the output power stage and operates to null the error signal defined as difference between the output of the sense amplifier 5 and the output of the DAC 2 whose input is fed by the serial port 1. A voltage reference 3 sets the output common mode voltage. In this configuration the power stage is implemented as a particular unipolar class G bridge amplifier.

The power transistors are indicated in FIG. 2 as NMOS transistors, but the same functions can be implemented utilizing bipolar transistors or PMOS transistors as well. The power devices may be driven in a conventional class AB or, more simply in class A in order to obtain low total harmonic distortion. What constitutes the Class G and determines its advantages is the fact that the high side drivers electrically coupled to VDD and VCC are alternatively turned on in response to the amplitude of the required voltage across the load.

If the stages are driven in class A, the full bridge low side drivers M1 and M2 always conduct a current that can be increased depending on the magnitude of the input signal. This can be achieved by forcing a constant common mode voltage at the output terminals of the bridge. When the required load current is low enough that it can be provided by the high side devices M5 and M6 electrically coupled to VDD, the control blocks 13 and 14 would prevalently drive these transistors M5 and M6.

When the required voltage across the load is increased, as in the case of seek mode operation, automatically the transistors M3 and M4 are activated and the transistors M5 and M6 are de-biased allowing higher voltage across the load. In the proposed embodiment a diode D1 is connected in series to the transistors M5 and M6 in order to prevent a current flow from the higher voltage power supply VCC to the lower voltage VDD. This diode could more efficiently be replaced by a switch that is turned on and off simultaneously with the transistors M5 or M6.

If, for example, the low side transistor M2 is on, and the voltage required to maintain the commanded load current is increased significantly, the transition between the transistor M5 and M3 is obtained by making sure that, for a certain intermediate load current, both transistors conduct so that the output signal distortion is kept very low. During the transition the current in the transistor M5 will decrease and before it has reached zero, the transistor M3 will already be turned on and its current will be gradually increased to the point of conducting the full load current.

The described smooth transition can be achieved in many ways. One proposed means is to drive the gates of the devices M3 and M5 with the same signal but with the addition of a voltage offset between the gate voltage of M5 and the gate voltage of M3. This offset guarantees that when the transistor M5 starts conducting the transistor M3 is turning off. The amplitude of this voltage offset determines the overlapping of conduction of the high side devices and ultimately the transition of conduction of the devices.

In particular, when the input signal amplitude is increased, the transistor M3 will start conducting when the transistor M5 approaches the triode region. When the input signal increases further, raising the voltage at the gates of the high side transistors the transistor M5 will turn off because its source voltage will be pulled up higher than its drain voltage by M3 turning on harder. The diode D1 will prevent the current from flowing in the transistor M5 in the opposite direction. It is important to note that during this time the transistor M6, at the other side of the bridge, is kept fully off.

In the specific case of the VCM for Hard Disk Drive application, during track follow operation the motor current is typically quite low, therefore the additional MOS transistors M5 and M6 and diode D1, or the switch in its place, do not need to exhibit very low on resistance to achieve high efficiency, therefore their utilization does not add significant cost to the total solution.

During track follow operation high resolution motor drive is required to precisely control the VCM head on the hard disk tracks during read/write operation. According to the present invention, during track follow, the current to the motor is provided by the lower voltage power supply, therefore the switching noise introduced by the spindle motor drive, typically connected to high voltage rail VCC, is not affecting the VCM drive.

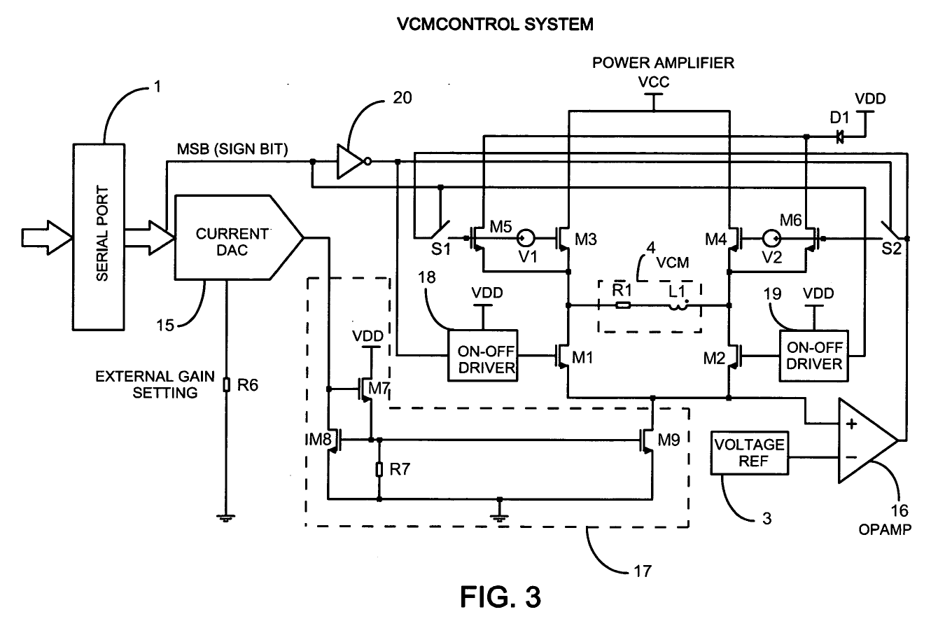

### B. FIG. 3

FIG. 3 shows a preferred embodiment of the present invention where the bridge Class G output stage is combined with the “imposed current” technique to remove the inner current control feedback. The shown VCM control system makes use of a Current Digital to Analog converter 15 whose output is in the form of an analog current whose value is set by the digital input of the DAC 15. This analog current is adjusted through an external resistor R6 and subsequently mirrored into the full bridge to drive the desired current in the VCM 4.

The full bridge is configured with two high side power transistors M3 and M4 electrically coupled to the power supply VCC, two high side power transistors M5 and M6 electrically coupled, through the diode D1, to the lower voltage power supply VDD and with two low side power transistors M1 and M2. The full bridge configuration allows the application of the full current to the load in both directions. The high side transistors may be P-type MOS or DMOS devices or N-type MOS or DMOS devices. The motor current is set by the current mirror 17.

The devices M8 and M9 constituting the power current mirror are sized differently in order to achieve the desired current ratio between the reference current, that being the output of the current DAC, and the output current value. The large size of the device M9 typically implies that the mirror's gate capacitance is proportionally significant, therefore a small reference current would limit the speed of a traditional current mirror. The transistor M7 and the resistor R7 increase the bandwidth of the current mirror with respect to its simplest and more conventional topology.

The low side transistors M1 and M2 are driven simply by turning the devices fully on or fully off. The signal that commands the low side drivers 18 and 19 can be derived from the MSB of the digital input of the DAC 15, since this bit represents the polarity of the current. This also has the effect to simplify the current output DAC 15, because the DAC output is simply a positive current.

The resistor R6, that can conveniently be external to the integrated device, is setting the gain of the servo loop. Since the current DAC 15 is working in one direction only, a true zero current should be passed to the load 4 when zero load is commanded. This implies that no DC offset is present and therefore the calibration phase, traditionally employed in conventional VCM systems, is no longer necessary. This configuration, if implemented appropriately, also guarantees a zero-cross distortion comparable to the one achieved by the more conventional class AB stage.

The current imposed in the motor is given by the ratio of the size of the transistors M8 and M9, however sometimes, especially when using DMOS transistors, it may be difficult to achieve the desired size of the reference transistor in relation to the size of the power transistor. This could lead to a current matching error which translates into a gain error in the system. Generally, this gain error is automatically corrected by the servo loop, but it could also be trimmed, in the integrated circuit, in several manners to obtain the desired gain.

It is important to note that when the maximum current in the VCM 4 is required, as is often the case for the seek mode operation, a high current is also flowing in the reference device M8 of the mirror 17 and generally, if the mirror transistors are sized properly, the gate voltage of the output transistor M9 is high enough to drive M9 in the triode region with minimum on-resistance. However, when either the maximum DAC digital input or an analog threshold is reached, an additional circuit that turns on a device to pull the gate voltage of the mirror output transistor to the maximum allowed voltage could be added. That would guarantee that the transistor M9 is fully turned on in that specific condition.

The operational amplifier 16 drives the high side devices in order to regulate the drain voltage of the mirror output transistor M9 to be at the same voltage of the voltage reference 3. This offers several advantages: it allows the use of low voltage rating MOS transistors for both of the current mirror devices, it guarantees a better current matching since the output impedance of the current mirror is not so critical and it keeps the conduction state of the transistor M9 at the edge of the triode and the saturation regions. Furthermore if the DC gain of the operational amplifier 16 is high enough, the transfer function of output current versus input signal amplitude is guaranteed to be very linear.

This regulation of M9 drain voltage is obtained by driving the high side devices accordingly. The gate voltages of the high side devices M3 and M5 are offset by the voltage V1, so that M5 is driven for low load current values consuming current from VDD, and M3 is driven for higher load current values consuming current from the power supply VCC. This transition from one high side transistor to the other is accomplished automatically depending on the amplitude of the input signal from the serial port 1. The same exact mechanism is occurring for the high side drivers M4, M6 and the voltage V2. The high side drivers M3 or M5 and M4 or M6 are selected through the switches S1 and S2 commanded by the MSB of the digital input of DAC 15 and the signal at the output of the inverter 20.

During the transition between one high side transistor and the other at the same side of the bridge, both high side transistors conduct and the amount of conduction overlap depends on the amplitude of the offset voltage V1 or V2. For example, when the gate voltage of the transistor M3 exceeds the voltage VDD-Vf(D1)+Vth(M3), the transistor M3 starts conducting and the transistor M5 decreases its current conduction proportionally. This occurs at a different gate voltage level for the transistor M5 depending to the voltage offset V1. The voltage offsets V1 and V2 do not have to match since the conduction overlap is not critical and it does not have to be necessarily symmetric. The diode D1 in series to the transistors M5 and M6 is preventing the current flow from the supply VCC to the supply VDD.

The elimination of the current loop that includes the error amplifier, the sense amplifier, and the external components associated with them simplifies significantly the implementation but, most importantly, makes the solution inherently stable, faster (not limited to the frequency compensation of the error amplifier), free of DC voltage offsets that normally require an initial calibration phase, smaller in die area, more easily testable, and certainly more accurate in particular when the DAC 15 is implemented as an oversampling converter.

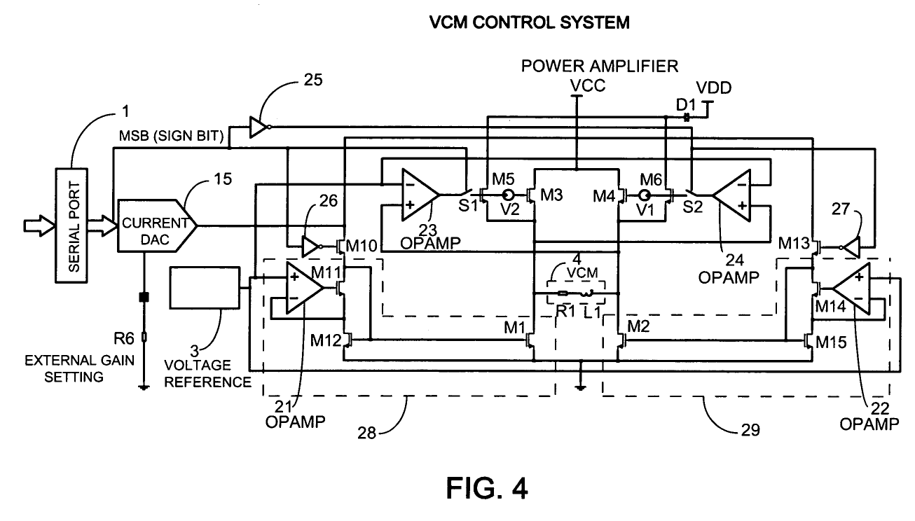

### C. FIG. 4

The embodiment of FIG. 4 shows an implementation of the class G bridge stage combined with the mirroring of the current into the power devices and into the load similarly to the embodiment of FIG. 3. In this embodiment the power current mirrors, designated as blocks 28 and 29, are two and this eliminated the series device M9 of FIG. 3. In this configuration the low side transistors M1 and M2 are part of the power current mirrors 28 and 29.

The power mirrors 28 and 29 are selected by means of the transistors M10 and M13 driven by inverters 26 and 27 according to the polarity of the MSB of the digital input signal of the DAC 15 that determines the direction of the current in the VCM load 4. The high side transistor gates are driven by the operational amplifiers 23 and 24 in order to regulate the voltage at the low side of the load to the voltage of the reference 3.

When a high side transistor is conducting current, the voltage at the drain of the conducting low side transistor, at the opposite side of the bridge, is regulated to be at a constant voltage. When the input signal amplitude is increased to the point that the high side transistor coupled to the lower voltage power supply VDD cannot deliver the requested load current, automatically the operational amplifier would drive the gate voltage of the high side transistors higher so as to drive the device electrically coupled to the higher supply voltage VCC and gradually turn off the devices coupled to VDD. Again during the transition both high side devices conduct current and the conduction overlap is dependent on the amplitude of the voltage offsets V1 and V2 between the gates of the high side transistors.

Similarly to the case of the operational amplifier 16 of FIG. 3, the operational amplifiers 23 and 24 are supplied by a higher voltage, typically a voltage generated by an on chip charge pump circuit, in order to drive the gates of the high side transistors at a voltage higher than VCC and to turn fully on the high side transistors when required. Similarly to the implementation of FIG. 3, the fact that the drain voltage of the conducting low side devices is regulated at low voltage guarantees that the current imposed by the power current mirrors is not dependent on the output impedance of the output devices M1 and M2 and it is therefore more signal independent.

The drawing of FIG. 4 is clearly only to depict the concept and more details may be needed to complete the implementation. In particular the turn off of the low side devices could be further guaranteed by additional switches at the gates of the transistors M1 and M2. Similarly the high side transistors may require additional devices to implement a fast reverse of current in the motor as it is often required for the seek mode of operation.

As is clear to those skilled in the art, this basic system can be implemented in many ways, and the above description is not limited to a specific implementation. Analogous known techniques make use of current mirrors and accurate voltage regulating circuits in various configurations. However, it is clear that the motor control may be implemented by imposing a current in the motor with bridge class G stages that switch the current to the load from one lower voltage power supply to a higher voltage one or vice-versa depending on the amplitude of the input signal as in the above described embodiments.

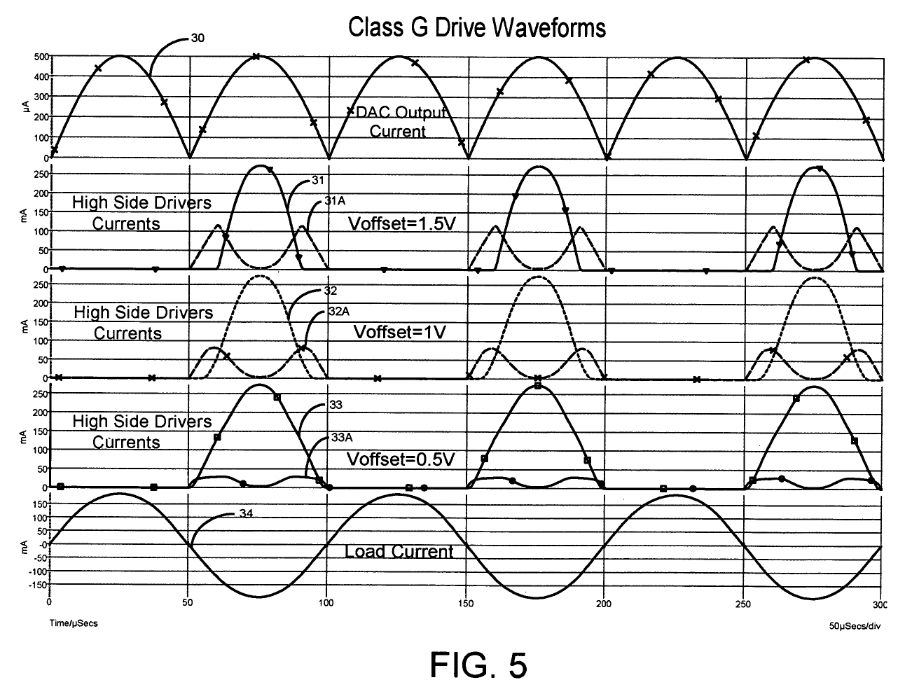

### D. FIG. 5

FIG. 5 depicts the main current waveforms for the embodiment of FIG. 3 or FIG. 4 for the case of a sinusoidal input signal and zero inductance of the motor. As previously described, the output of the DAC is represented by a sinusoidal current that is always positive as shown by waveform 30. The currents in the high side transistors of one half bridgevarying the input signal is shown in the three center waveforms for different amplitude values of the voltage offsets between the gates of the high side transistors.

In particular, the waveforms 31 and 31A show the currents in the high side transistors M5 and M3 respectively if the offset voltage is 1.5V. The waveforms 32 and 32A show the same high side transistors currents if the offset voltage is 1V. The waveforms 33 and 33A show the same high side transistors currents if the offset voltage is 0.5V. As it can be seen, the transition in current conduction between one high side transistor to the other one is dependent on the amplitude of this offset voltage. The higher this offset voltage, the larger is the current conducted by both devices during the transition. This smooth handoff of the current is what guarantees low distortion of the load current. The bottom waveform 34 is the resultant sinusoidal current in the load for the three cases.

Although the present invention has been described above with particularity, this was merely to teach one of ordinary skill in the art how to make and use the invention. Many additional modifications will fall within the scope of the invention. Thus, the scope of the invention is defined by the claims which immediately follow.

What is claimed is:

1. A load driver system comprising:
a load having two terminals;
a pair of half bridge power circuits, each having an output terminal coupled to respective terminals of said load, and
a pair of power amplifier circuits coupled to respective said half bridge power circuits;
wherein said half bridge power circuits are comprising a first high side transistor having current path connected between a rectifier connected to a first voltage source and said output terminal, a second high side transistor having current path connected between a second voltage source and said output terminal, and a low side transistor having current path connected between said output terminal and the electrical ground terminal;
wherein said power amplifier circuits receive a signal representative of the current to be applied to said load and drive said high side transistors and said low side transistors of said half bridge circuits to establish a desired current path through the selected transistors and said load;
wherein said first voltage source is at lower voltage, said second voltage source is at higher voltage and said rectifier coupled to said first voltage source is placed to allow a current path from said first voltage source to said first high side transistor, and to block current flow between said second voltage source and said first voltage source, and
whereby said power amplifier circuits drive alternatively said first and second high side transistors in response to the amplitude of the required voltage across the load, such that for lower desired voltages across the load said first high side transistor is conducting and for higher desired voltage across the load said second high side transistor is conducting.

2. The load driver system of claim 1 wherein said load is a motor.

3. The load driver system of claim 1 wherein said rectifier coupled to said first voltage source is a transistor turned on simultaneously to said first high side transistor.

4. The load driver system of claim 1 wherein said rectifier in each half bridge power circuit is replaced by a single rectifier in common with said pair of half bridge power circuits.

5. The load driver system of claim 1 wherein said low side transistor of said half bridge power circuit has current path connected between said output terminal and a common current source.

6. The load driver system of claim 1 wherein said power amplifier circuits drive the gate terminals of said first high transistors with a voltage signal and the gate terminals of said second high side transistors with said voltage signal offset by a substantially fixed voltage.

7. The load driver system of claim 1 wherein said power amplifier circuits operate to establish a desired current path through the selected transistors and said load by regulating the common mode voltage at the terminals of said load.

8. The load driver system of claim 1 wherein said load is a multiphase motor with multiple terminals coupled to multiple half bridge power circuits.

9. The load driver system of claim 1 wherein said half bridge power circuit comprises a multiplicity of high side transistors connected to a multiplicity of voltage sources.

10. The load driver system of claim 1 wherein said load is a motor used in a magnetic or an optical data storage system.

11. A method for achieving efficient driving of a load, comprising:
generating a signal representative of the voltage to be applied to said load;
receiving power from a first voltage source operating at a first voltage and a second voltage source operating at a second voltage higher than said first voltage;
driving a bridge power amplifier coupled to said load, wherein each half bridge power circuit of said bridge power amplifier is comprising a first high side transistor having current path connected between a rectifier connected to said first voltage source and a terminal of said load, a second high side transistor having current path connected between said second voltage source and said terminal of said load and a low side transistor having current path connected between said terminal of said load and the electrical ground terminal;
applying a voltage signal to the gate terminal of said first high side transistor and said voltage signal offset by a substantially fixed voltage to the gate terminal of said second high side transistor of said half bridge power circuit;
receiving said signal representative of the voltage to be applied to said load;
commanding said first high side transistor, said second high side transistor and said low side transistor of each half bridge power circuit of said bridge power amplifier to establish a desired current path through the selected transistors and said load, and
applying voltage to said load by means of said half bridge power circuits of said bridge power amplifier to drive said first high side transistor or said second high side transistor depending on the amplitude of said signal representative of the voltage to be applied to said load;
whereby for low required amplitude voltages across said load said first high side transistor electrically coupled to said first voltage source is conducting and for higher required amplitude voltages across said load said second high side transistor electrically coupled to said second voltage source is conducting.

12. The method of claim 11 wherein said rectifier coupled to said first voltage source is a transistor turned on simultaneously to said first high side transistor.

13. The method of claim 11 wherein said rectifier in each half bridge power circuit is replaced by a single rectifier in common with said half bridge power circuits.

14. The method of claim 11 wherein said half bridge power circuit comprises a multiplicity of high side transistors connected to a multiplicity of voltage sources.

15. A method for achieving efficient current driving of a motor, comprising:
generating a signal representative of the current to be applied to said motor;
receiving power from a first voltage source operating at a first voltage and a second voltage source operating at a second voltage higher than said first voltage;
driving a bridge power amplifier coupled to said motor, wherein each half bridge power circuit of said bridge power amplifier is comprising a first high side transistor having current path connected between a rectifier connected to said first voltage source and a terminal of said motor, a second high side transistor having current path connected between said second voltage source and said terminal of said motor and a low side transistor having current path connected between said terminal of said motor and the electrical ground terminal;
receiving said signal representative of the current to be applied to said motor;
commanding said first high side transistor, said second high side transistor and said low side transistor of each half bridge power circuit of said bridge power amplifier to establish a desired current path through the selected transistors and said motor, and
applying said current to said motor by means of said half bridge power circuits of said bridge power amplifier to drive said first high side transistor or said second high side transistor depending on the required amplitude of the voltage across said motor in response to said signal representative of the current to be applied to said motor;
whereby for low required amplitude voltages across said motor said first high side transistor electrically coupled to said first voltage source is conducting and for higher required amplitude voltages across said motor said second high side transistor electrically coupled to said second voltage source is conducting.

16. The method of claim 15 wherein a multiplicity of voltage sources is electrically coupled to multiple high side transistors of said bridge power amplifier.

17. The method of claim 15 wherein said rectifier coupled to said first voltage source is a transistor driven simultaneously with said first high side transistor.

18. The method of claim 15 wherein said low side transistor of said half bridge power circuit has current path connected between said output terminal and a common current source.

19. The method of claim 15 wherein said motor is used in a magnetic or an optical data storage system.

20. The method of claim 15 wherein said motor is a multiphase motor with multiple terminals coupled to multiple half bridge power circuits.
